(19) United States
(12) Patent Application Publication
(10) Pub. No.: US 2009/0223553 A1
(43) Pub. Date: Sep. 10, 2009

(54) SOLAR ENERGY COLLECTION SYSTEM

(75) Inventor: Dennis Thoroughgood, Victoria (AU)

Correspondence Address: KNOBBE MARTENS OLSON & BEAR LLP, 2040 MAIN STREET, FOURTEENTH FLOOR, IRVINE, CA, 92614, US

(73) Assignee: World Energy Solutions Pty Ltd., Hawthorn, Victoria (AU)

(21) Appl. No.: 11/721,152

(22) PCT Filed: Dec. 9, 2004
(86) PCT No.: PCT/AU04/01734

§ 371 Date: Dec. 15, 2008

Related U.S. Application Data
(60) Provisional application No. 60/618,327, filed on Oct. 13, 2004.

(30) Foreign Application Priority Data
Dec. 11, 2003 (AU) 2003906865
Sep. 8, 2004 (AU) 2004905104

(51) Int. Cl. H01L 31/052

(52) U.S. Cl. 136/246

(57) ABSTRACT

A collector (2) for concentrating radiation (5), preferably solar radiation, and an energy collection system (1) that includes the collector, which concentrates the radiation along an elongate region of a body which converts the radiation into electrical and/or heat energy. A lens (10) is also disclosed for use in the system, which has a focal plane extending normally of the lens.

### FIELD OF INVENTION

The present invention relates to an energy collection system.

In one form, the invention has application for use with systems which convert solar energy to heat and/or electrical energy, such as with photovoltaic cells.

It will be convenient to hereinafter describe the invention in relation to use with photovoltaic cells (PV cells), however, it should be appreciated that the present invention is not limited to that use only.

### BACKGROUND OF THE INVENTION

It is known to use photovoltaic cells to produce electricity from photonic radiation received from the sun. The photovoltaic cells are conventionally mounted on a flat panel, beneath a protective glass layer, in an array which extends over substantially an entire face of the panel, in order to maximise electrical output. The panel may be mounted on a dual-axis tracking assembly to allow the panel to continually face the sun.

There are a number of problems that currently exist in and around the use of prior art PV cells and panels, such as:
The cost of current PV cells for households is considered too expensive relative to output efficiency. With an average existing panel and even with high efficiency cells and tracking of the sun, only about 30% of solar energy is converted to useful output,
The amount of light incident on each cell may be increased such as with a point focus concentrator lens over each cell but then there is a need to limit the extent of solar energy concentrated because of degradation of the PV cells due to varying energy intensities and/or temperature rise across a collection plane of each cell,
In relatively high energy concentrator arrangements, the use of magnification with the PV cells means that the cells need to be actively cooled. The resultant heat energy is typically dumped even though it can be up to four times the amount of energy gained electrically from the PV cells (depending on cell efficiency),
To achieve relatively maximum output from solar panels, it is necessary to track the sun. The electrical output of a panel with photovoltaic cells operating at, for example, 17% efficiency can be increased by an average of 60% using such a tracking assembly in regions of, say, 37° latitude to provide an effective increase in cell efficiency to 27%. However, provision of a tracking system can be prohibitively expensive as a result of equipment costs and parasitic power drain required to drive the assembly.
The inventors have realised that without tracking, the acceptance angle for solar rays is relatively low for extended periods and the power produced, therefore, is much reduced,
The inventors have realised that existing tracking regimes have many reliability problems. One such problem is having to track the sun in two dimensions. It is considered that the parasitic energy losses are too large compared with the power generation required for industrial and commercial installations,
The inventors also realise that there is a relatively high fixed cost for PV systems, particularly those in excess of 5 square metres, which would be required to supply electrical energy as well as functioning as a solar heating system. A solar heating system of this size adds significantly to the cost and size of an installation, without giving significant heating energy for practical use.

Any discussion of documents, devices, acts or knowledge in this specification is included to explain the context of the invention. It should not be taken as an admission that any of the material forms a part of the prior art base or the common general knowledge in the relevant art in Australia or elsewhere on or before the priority date of the disclosure and claims herein.

### SUMMARY OF THE INVENTION

In accordance with one inventive aspect of the invention, there is provided a method of collecting and an energy collection system with a lens for concentrating radiation along an elongate region of a body which converts the radiation into electrical and/or heat energy.

In accordance with another inventive aspect of the present invention, the lens is designed to have a focal plane extending substantially normally of the lens such that incident radiation on a face of the lens is refracted in a manner substantially uniformly over the region. Preferably, the lens is a Fresnel lens.

In accordance with a further aspect, a cradle is provided and adapted for use with a solar energy collection system, as described above, the cradle including a first wall, having a first surface which is provided substantially in line with a position of the sun at the winter solstice, a second wall having a second surface which is provided substantially in line with the position of the sun at the summer solstice.

Preferably, at least one of the first and second surfaces are at least partially light reflective.

In accordance with a still further aspect of the present invention, there is provided a tooth adapted for use with a lens in a solar energy collection system, the tooth being designed in accordance with equation 1, 2 and/or 3 as disclosed herein.

The lens concentrates the incident solar radiation onto the elongate region of a body adapted to convert the radiation into electrical and/or heat energy.

In accordance with another inventive aspect, the lens is supported on a cradle provided with pivot structure to allow for rotation generally only in an east/west direction, transverse to the elongate region, in order to track the incident radiation.

Other aspects and preferred aspects are disclosed in the specification and/or defined in the appended claims, forming a part of the description of the invention.

With the above arrangement, it is possible to concentrate the suns energy onto an array of fewer PV cells, as compared to a flat panel arrangement, to get relatively and approximately the same electrical power output from the PV cells through an increased operating temperature of the cells. The inventors have further realised that the concentrator can be designed to give a more even intensity of solar concentration across the PV cells. The particular shape of the cradle enables the use of single axis tracking, whilst still gaining relative improvements in efficiency in the use of the PV cells. This is due to the fact that the focused light travels up and down the array and reflective end walls throughout the year whilst still maintaining full illumination on the array. Any light incident on the reflective surfaces of the cradle walls will be reflected also onto the array with relatively minimal losses. The use of a Fresnel lens with a reduced area array of PV cells also has been realised to give significant improvement in electrical output power from the PV cells, above the output from an array of PV cells having no lens but the same size area as the lens, due to higher operating temperatures of the cells.

Furthermore, it has been realised that by using a system of cooling, the energy collected can be additionally harnessed for household and industrial use, due to the more concentrated surface area of the array and higher operating temperature, instead of the energy being dumped as low temperature waste energy, as with a conventional system. Consequently, the integration of solar heating into the present PV cell (concentrator) system may give greater output as well as at a relatively lower cost.

A number of possible advantages may be realised with the above, such as:
The use of fewer cells bringing about a reduction in capital cost,
The operation of cells at a higher temperature allowing energy from sun, additional to that converted to electrical energy by the PV cells, to be converted to useful heat energy, to give a total energy conversion output of in the order of 90% of solar energy collected,
The use of a Fresnel lens giving a more uniform concentration of incident radiation across the PV cell array,
A concave/convex lens with a relatively large focal length possibly being used,
A vertical projection design for the Fresnel lens being adopted, providing the benefits of the normal Fresnel type lens whilst further ensuring the uniformity of the intensity over the PV cells,
The level of magnification determined for the lens allowing the temperature of any water heated by the system to be the regulated to household temperature. This water may also be used in a feed system to pre-heat households hot water,
The cradle dimensions and reflective internal surfaces allowing for the system to operate with only single direction tracking,
The use of a relatively simpler tracking system providing for increased reliability,
The system being used to provide a household's entire energy needs giving more cost effective electrical energy production plus additional energy conversion in the form of useful heat energy production.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

Further disclosure, objects, advantages and aspects of the present application may be better understood by those skilled in the relevant art by reference to the following description of preferred embodiments taken in conjunction with the accompanying drawings, which are given by way of illustration only, and thus are not limitative of the present invention, and in which:

FIG. 1 is a diagrammatic perspective view of one embodiment of an energy collection system;

FIG. 2 illustrates various views of one embodiment of a collector and body of the system of FIG. 1;

FIG. 3 is a diagram illustrating Fresnel's law of refraction;

FIG. 4 is a cross-sectional view of a lens and photovoltaic array of the system of FIG. 1, taken along the line A-A;

FIG. 5 is a view similar to that of FIG. 4, showing the affect of a change in direction of incident radiation;

FIG. 6 illustrates various views of a light sensor for use in a tracking system; and

FIG. 7 is a chart illustrating power output of photovoltaic arrays.

### DETAILED DESCRIPTION

One embodiment of the present invention includes 4 elements, namely:

Fresnel Lens,

Collection Cradle with PV cell array,

Cooling System providing Preheated Water, and

Sun Tracking System

These are further disclosed herein below.

### 1. Overall System

The present invention, and its various aspects:
Utilizes a specifically designed Fresnel type lens to concentrate the sun's radiation onto photovoltaic cells to produce electrical energy,
Applies at least one strip of photovoltaic cells to the base of a walled cradle. The length of the strip is determined by the location of the system in the world, relative to the conditions of the sun's rotation to that location. The walls of the cradle are preferably reflective to increase the energy collection by virtue of the walls reflecting additional light onto the cells and/or to offset any variation in sunlight due to clouds in the north-south direction and any seasonal variations in the latitude of the sun. This allows minimal light loss and maintains a high efficiency of energy collection,
Maintains acceptable operating temperature of the PV cells and increases the system's efficiency by routing cooling tubes behind the PV cells and on the walls of the cradle,
Uses heat energy collected by the cooling tubes to pre-heat water for household purposes, so utilizing the electrical conversion inefficiencies of the PV cells and maximizing the system efficiency by collecting heat energy,
Tracks the movement of the sun on the east west axis to gain a high level of energy collection from the sun. The parasitic energy losses otherwise required from tracking variations of sunlight on the north south axis are therefore avoided,
The system creates from the energy collected from the sun, heat and electrical energy through the use of a concentrator lens, cradle, photovoltaic cells and cooling tubes,
Some of the particular aspects of the invention include the lens, collection cradle, the combination of pre-heating water by cooling the photovoltaic cells as a feed to the household hot water system and the ability to utilise a single axis method of tracking,
The Fresnel type lens concentrates the suns rays to increase the output efficiency with respect to cell area,
The collection cradle is inclined appropriate to the latitude of it's location to give greater face to the north/south direction as appropriate, according to the geographic latitude of the location of the installation of the system. In this way, the cradle is capable of collecting and reflecting the sun's rays from the north or south direction to give a high intensity of sun without changing the inclination of the photovoltaic cells,
Water used to cool the photovoltaic cells can be circulated into a storage tank to provide preheated water for the household hot water system,
To ensure the photovoltaic cells are oriented to the strongest sunlight, a drive system rotates the cradle using a tracking system to determine the direction of the cradle which will maximize the energy collection, and
It has been found that design principles of a Fresnel lens can be applied in respect of the lens, collector and/or cradle of the present invention.

### 2. The Fresnel Lens

As illustrated in FIG. 4, the present invention utilises a particular design for the Fresnel lens.

The Fresnel lens is designed, according to this embodiment, to give a maximum concentration of the sun's rays across the surface of each cell whilst maintaining a uniform intensity on the cells. This is achieved by designing the lens to have a focal plane perpendicular to the face of the lens. This overcomes concentration problems associated with non-uniform light intensities on the collection areas. The choice of Fresnel lens over a mirror or other lens also ensures uniform light projection due to clarity of imaged light.

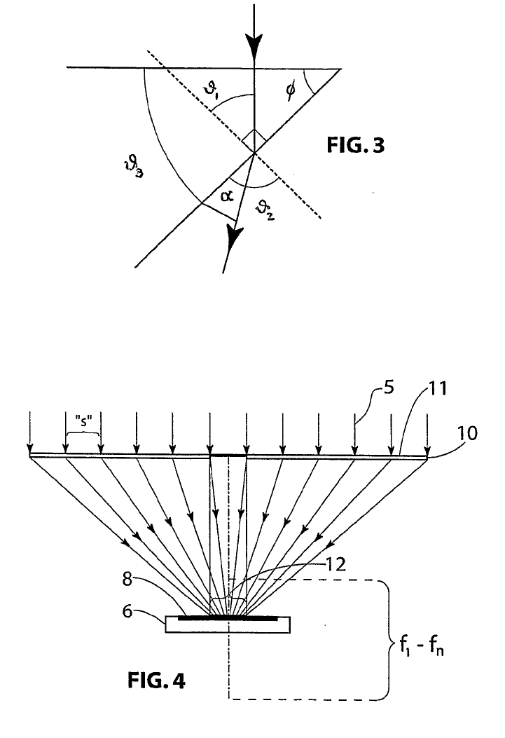

The general design considerations taken into account in constructing a lens 10 (of FIG. 4) are discussed with reference to FIG. 3 with general equations used for calculating the structure of the teeth of the lens 10 and the law of refraction being:

n₁ sin θ₁=n₂ sin θ₂ (1)

where

n₁ index_of_refraction (incedent_ray)

n₂=index_of_refraction (refracted_ray)

θ₃=φ+α

θ₁=φ

θ₂=90−α

α=90−θ₂

α=θ₃−φ

90+θ₃−α=θ₃+θ₂

With a Fresnel lens, different sections of the lens can be designed to focus at different positions to enable a substantially uniform concentration of the light. For example, FIG. 4 shows a lens 10 with substantially saw-tooth shaped teeth either side of a middle region. The middle region has little, if any, concentration of light on the cells. With an image at a desired focal distance “f₁-fₙ” representing the focal length of the first to the nth tooth, basic trigonometry is used to determine the angle between the image and the horizontal or the refractive surface, as per equation (2). Thus, the present invention can be used to design a lens and collector of various sizes and shapes. From this, the angle of the hypotenuse to the horizontal in the refracting tooth can be found through equation (3). Equation (3) is a derivation of the law of refraction as stated previously.

$${ϑ}_{3} = {tan}^{- 1} ( \frac{{f}_{1}}{{x}_{f}} ) \qquad ( 2 )$$

where

f₁=focal_length

x_{∫}=horizontal_dislacement_to_focal_point

$$φ = {tan}^{- 1} ( \frac{sin ( 90 - {ϑ}_{3} )}{\frac{{n}_{1}}{{n}_{2}} - cos ( 90 - {ϑ}_{3} )} ) \qquad ( 3 )$$

From the combination of equations (2) and (3), any Fresnel type lens can be designed.

The Fresnel lens 10, designed for the collection system, is shown in FIG. 4. The lens 10 is divided up into any number of sections “s”. In a preferred form, there are ten sections “s”, each focusing in ten different areas, each tooth in each section having a corresponding focal length. If ray tracing is used to determine the absolute focal point of the lens, a perpendicular focal area would be found. This differs from normal lenses as they generally all have a parallel focal plane. It has been found that with a perpendicular focal plane, a more uniform concentration of radiation can be achieved along and across the region 12 of the body 6. Accordingly, the lens 10 can focus radiation from across the face 11 of the lens 10 onto a substantially uniform elongate region of the array 8 of photovoltaic cells. Further, the intensity of radiation applied to the region 12 is increased or magnified by a factor commensurate with the temperature of the cell or the desired heat required. For example, the factor may be 11, depending on the characteristics required for a safe operating temperature of the elongate body, as compared to the intensity that would otherwise be available if light was simply allowed to be directly incident on that region, without being magnified by a lens.

### 3. Collection Cradle

The collection cradle has parameters which are specific to the location on the earth's surface relative to the equator to maximise illumination on the PV array. The closer the system is to the equator, the longer the collection strip of PV cells can be, relative to the size or length of the base of the cradle. This is due to the smaller variation in the path of the sun throughout the year.

This specific selection of array length, increases the efficiency of the system, minimizing the light that has to be reflected onto the array. However, the indirect illumination of the array by light reflected off the side walls of the cradle onto the array, increases the efficiency that would otherwise apply if only the light directly illuminating the array was used.

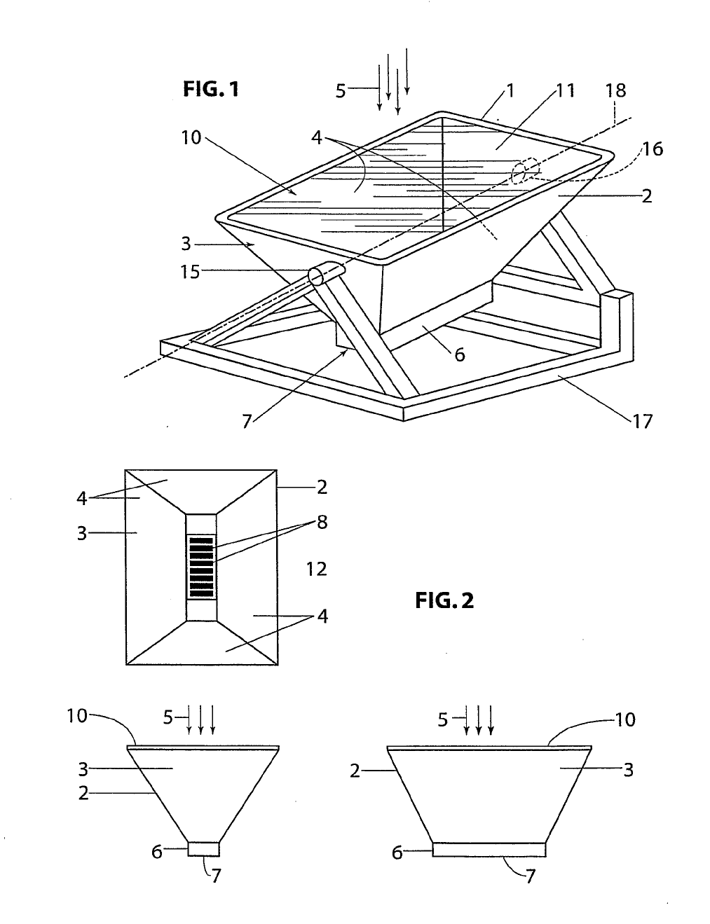

A particular configuration of the energy collection system 1 is shown in FIGS. 1 and 2 as including a collector 2, in the form of a cradle 3 with reflective walls 4, for concentrating radiation 5 onto a body 6 at a base 7 of the cradle 3. The body 6 preferably carries an elongate strip or array 8 of photovoltaic cells and is provided with suitable electrical connections (not shown) to allow the body to be readily inserted and/or removed and replaced in the base 7, in a cartridge like manner.

The lens 10 is provided over the cradle 3 to assist in concentrating the radiation 5, which is incident on a face 11 thereof, onto an elongate region 12 of the body 6. For that purpose, the lens preferably has a focal plane extending in a direction away from the lens 10 and through the body 6 such that the incident radiation 5 is refracted substantially uniformly over a transverse and elongate area of the region 12 of the body 6.

The cradle may also have the following:
A first wall, having a first surface which is provided substantially in line with the position of the sun at the winter solstice,
A second wall having a second surface which is provided substantially in line with the position of the sun at the summer solstice, and
Each of the first and second surfaces being light reflective.

The cradle is preferably also adapted to have the lens span entirely between the first and second walls.

In one form, the first and second walls are disposed at an angle in the range of 90 to 130 degrees relative to a flat surface of the body.

Preferably, for a latitude such as Melbourne, Australia, the first and second walls are disposed at an angle of substantially 115 degrees to the horizontal.

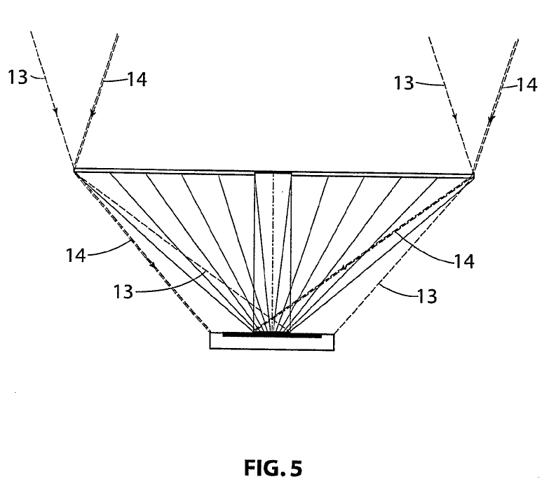

The positioning of the region 12 is shown in FIG. 4 in a centralised location relative to the body 6, due to the radiation 5 being incident on the lens 10 from a substantially normal direction. If the direction of the incident radiation is changed, such as indicated by arrows 13 or 14 in FIG. 5, the region 12 would simply travel to the right or left respectively, as viewed. The total length of the body 6 and associated array 8 may therefore be determined by reference to the maximum directional change in the incident radiation 5. In circumstances where the system 1 is used to collect solar energy, the body 6 and related elongate region 12 may be arranged to extend in a generally north/south direction such that any seasonal variation in the positioning of the sun will be automatically accommodated in the system 1 by virtue of the region 12 simply travelling up and down the extent of the body 6.

The system 1 will, however, preferably actively track the sun from east to west. For that purpose, pivots 15, 16 are provided, as shown in FIG. 1, to couple the cradle 3 to support structure 17 such that the cradle 3 is able to pivot about an axis 18 which is transverse to a longitudinal direction of the body 6 and elongate array 8.

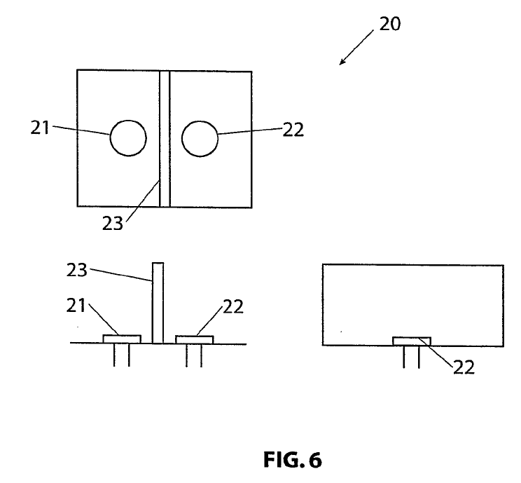

To facilitate tracking movement, the system 1 may include a tracking mechanism (not shown) which employs a light sensor arrangement 20, as shown in FIG. 6.

### 4. Cooling System Providing Preheated Water

A heat transfer assembly may be provided which includes cooling water tubes (not shown) located in the base and on the sides of the cradle. Water is circulated through the tubes at a rate which keeps the photovoltaic cells and cradle surface at an acceptable temperature, for example, 60 degrees Celsius.

This water is returned to a header tank and is used for example as feedwater for a hot water system of a building or other building/process systems requiring heat energy.

Through this process, significant solar energy is converted into heat energy by the system giving additional useful energy not otherwise achieved from the current large flat PV arrays which are used.

Such heat transfer systems have not previously been practically implemented with existing photovoltaic panel arrangements since the cells operated at too low a temperature. However, the photovoltaic cells of the present system 1, can operate at substantially higher temperatures due to the increased concentration of radiation afforded by the collector 2.

### 5. Sun Tracking System

In conjunction with the lens concentration and the cradle design, an adaptation of an existing tracking system can be made. The cradle allows collection of light energy to be largely unaffected by the movement of the sun in the north south axis. Because of this a two-axis tracking system is not needed (azimuth and elevation). With the ability to use a single axis tracking system the parasitics on power, being the control and drive mechanisms are halved, another way of increasing efficiency.

For tracking, light dependant resistors are used with a fin arranged between them to determine the position of the sun. To further develop this and overcome existing problems with tracking systems greater emphasis has been put into conditional control. Values for different resistors and ranges on their deviation from one another have been included to stop unnecessary driving of the system. Tracking is the major inherent energy loss and by tracking in one direction only, the loss is half that of the conventional dual axis tracking.

With the traditional tracking system, when one resistor of a set of light sensitive resistors was of a higher magnitude, the drive train would drive in the other direction (sun light causes the resistance value to drop in magnitude). However, with cloud cover, light is scattered and it is possible from one moment to the next, due to density of cloud, for the sun to appear as if it is in a different location.

Tolerances have been introduced to govern when the system will and won't drive. If the resistance values are both high then the system won't track. If both the resistances are low and there is only a slight variation, within a tolerance value, the system won't drive. The system will only drive through the resistor interpretation if one of the resistance values is high and the other one is low. The system will also contain set drive times if there is only high resistor input such as morning midday and night.

In one embodiment, the arrangement 20 includes two light sensitive resistors 21, 22 positioned on either side of a shading fin 23, which extends in a north/south direction. When resistance in one of the resistors changes, the sun is assumed to have moved to one side or the other of the shading fin 23 and the cradle 3 may then be driven in the appropriate direction to realign the shading fin 23 with the sun and equalise the resistive load in each resistor 21, 22. Tolerances may be introduced to govern when the mechanism will and won't drive, in order to accommodate minor changes in environmental circumstances which may affect the amount of light falling on either of the resistors 21, 22. The mechanism may also be subject to set drive times such as for morning and night.

### 6. Research Results

It may be appreciated from the above that significant solar energy is gained by utilising the system 1, which would not otherwise be obtained using the current flat panel photovoltaic arrays. More specifically, experimentation for a cradle 3 fitted with a lens 10 of length in the order of 2.0 m and width in the order of 1.4 m for regions of 37° latitude (such as Melbourne, Australia), has produced very favourable results, as compared to conventional flat panel arrangement. To recap, a conventional photovoltaic panel having the same collection area as the cradle 3, with the inclusion of dual-axis tracking, will increase the electrical output of the panel, for example having 17% efficient cells (typically efficiency of commercially available photovoltaic cells) by an average of 60% to effectively 27% efficient cells. It should again be noted, however, that tracking systems are not generally used with photovoltaic panels because of the relatively high parasitic power losses involved, high equipment costs and generally low reliability because dual-axis tracking is required.

Tracking systems are typically not used in standard systems because of the relatively high parasitic losses involved, the high relative cost and generally low reliability because two axis tracking is required.

The concentrator system as described here increases the electrical output, for the given collection area, by an average of 72%, giving effectively 29% efficiency.

Not only will the concentrator increase electrical output by 12% compared with the tracking flat solar panel, but because only a strip of cells is used, compared with a whole array of cells for the conventional panel, the system cost is reduced by at least 50% (depending on manufacturing quantities). This price reduction is a combination of the reduced quantity of PV cells and less equipment and materials for the tracking system.

For the proposed configuration, the system achieves a cell output efficiency, in excess of the most efficient photovoltaic cells commercially available at much lower price.

A comparison of the output powers for a flat plate panel, a tracking flat plate and the present concentrator is shown below.

This shows a 50-60% improvement between flat plate and tracking flat plate systems, but for the concentrator system (for which the improvement would be 72% for the same collector area) the increase in power output per cell is increased approximately 5 times.

Through the cooling system, the concentrator will virtually allow 90% of the energy collected to be obtained. This is significantly greater than could be obtained for a tracking plate panel used with a solar water heating system.

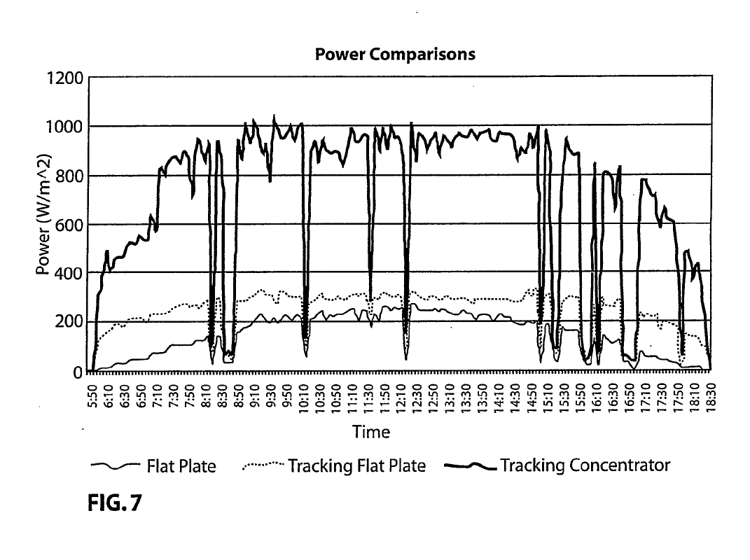

As noted above, the system 1 has been found to increase electrical output, for the given collection area, by an average of 72%, giving effectively 29% cell efficiency. More particularly, a comparison of the output powers for a flat panel, a tracking flat panel and the system 1 is shown in FIG. 7. Graph 28 illustrates the output for a flat panel without tracking. Graph 29 illustrates the power output for a flat panel with dual-axis tracking, which shows a 50-60% improvement over the graph 28. Graph 30 represents the output from system 1, which shows improvement of 72% for the same collector area as the panel. Of note also is that the power output per cell is increased approximately 5 times.

Aside from providing an increase in electrical output by an additional 12%, as compared with the tracking solar panel, the system 1 can also offer considerable manufacturing savings. For example, savings may be realised on equipment and parts as only single axis tracking is used, as opposed to dual-axis tracking, and only a strip of cells is needed in the system 1 as compared with a whole flat array of cells for the conventional panel.

Regardless of set-up costs though, it is significant that the system 1 achieves a photovoltaic cell output efficiency in excess of photovoltaic cells commercially available at present, by operating the cells under increased radiation intensity and at elevated temperatures. The elevated operating temperature also makes viable the use of a heat transfer assembly for cooling so that in the order of 90% (more or less) of incident solar energy may be captured by the system 1. That level of efficiency is clearly significantly greater than could be obtained with a tracking flat panel in combination with a solar water heating system.

Also, with the above-described invention, it is possible to considerably reduce the number of cells otherwise required for the same collected energy, giving a significant reduction in the cost of the energy from the system as compared with the conventional solar array.

The system 1 has been described by way of non-limiting example only and many modifications and variations may be made thereto without departing from the spirit and scope of the invention described. For example, reference has been made throughout the specification to solar energy but the invention has application to collection of any type of radiation.

### LIST OF FEATURES

1. Energy collection system
2. Collector
3. Cradle
4. Walls
5. Radiation
6. Body
7. Base
8. Array
10. Lens
11. Face
12. Elongate region
13. Incident radiation
14. Incident radiation
15. Pivot
16. Pivot
17. Support structure
18. Axis
20. Light sensor arrangement
21. Resistor
22. Resistor
23. Shading fin
28. Graph
29. Graph
30. Graph

1. An energy collection system with a collector for concentrating radiation along an elongate region of a body which converts the radiation into electrical and/or heat energy.

2. A system as claimed in claim 1, wherein the body includes an elongate array of photovoltaic cells.

3. A system as claimed in claim 2, wherein the collector has a lens with a focal plane extending in a direction away from the lens and through the array such that radiation incident on a face of the lens is refracted substantially uniformly over the elongate region of the body.

4. An energy collection system with a collector for concentrating radiation substantially uniformly over an array of photovoltaic cells.

5. A system as claimed in claim 4, wherein the radiation is concentrated along an elongate region of the array.

6. A system as claimed in claim 2, wherein the collector is in the form of a cradle and the body is provided in a base of a cradle.

7. A system as claimed in claim 6, wherein the cradle is arranged to pivot in a direction transverse to the elongate array.

8. A system as claimed in claim 6, wherein the cradle pivots in an east/west direction and the array extends generally in a north/south longitudinal direction, whereby the cradle is pivoted about an axis of the body to follow movement of the sun.

9. A system as claimed in claim 8, wherein the cradle is also arranged such that the axis is inclined toward the equator dependent on latitude of location of the cradle, to maximize radiation onto the collector.

10. A system as claimed in claim 6, wherein the cradle is provided with reflective walls angled according to a latitude of a location of the cradle to maximize the radiation onto the body so as to offset seasonal variations in the latitude of the sun.

11. A system as claimed in claim 1, further including a heat transfer assembly for collecting and storing heat from the body.

12. A system as claimed in claim 11, wherein the heat transfer assembly includes tubing in thermal communication with the body.

13. A system as claimed in claim 11, wherein the heat transfer assembly, in combination with the elongate array, enables for in the order of 90% of the radiation received by the collector to be converted into useful electrical and/or heat energy.

14. A collector, in the form of a cradle, for use in the system as claimed in claim 1, and including a pivot structure to allow for rotation generally only in an east/west direction.

15. A lens having a focal plane extending substantially normally of the lens.

16. A lens as claimed in claim 15, wherein the lens is a Fresnel lens.

17. A method of energy collection, including concentrating incident solar radiation through a collector and onto an elongate region of a body adapted to convert the radiation into electrical and/or heat energy and pivoting the collector in a direction transverse to the elongate region in order to track directional changes in the incident radiation.

18. A method as claimed in claim 17, wherein the collector is pivoted in an east/west direction only.

19. A cradle adapted for use with a solar energy collection system, the cradle including:
a first wall, having a first surface which is provided substantially in line with a position of the sun at a winter solstice.
a second wall having a second surface which is provided substantially in line with the position of the sun at a summer solstice, and
at least one of the first and second surfaces being at least partially light reflective.

20. A cradle as claimed in claim 19, wherein the first and second walls are disposed at an angle in the range of 90 to 130 degrees to the horizontal.

21. A cradle as claimed in claim 19, wherein the first and second walls are disposed at an angle of substantially 115 degrees to the horizontal.

22. A tooth adapted for use with a solar energy collection system, the tooth being designed in accordance with equation 1, 2 and/or 3 as disclosed herein.

23. A lens adapted for use with a solar energy collection system, including a tooth as claimed in claim 22.

24. A method of configuring a tooth for use with a lens in a solar energy collection system, the method including the step(s) of providing a tooth in accordance with equation 1, 2 and/or 3 as disclosed herein.

25. A lens as claimed in claim 23, wherein the lens is a Fresnel lens.
